(19) United States
(12) Patent Application Publication
(10) Pub. No.: US 2024/0186117 A1
(43) Pub. Date: Jun. 6, 2024

(54) ATOMIC LAYER DEPOSITION APPARATUS

(71) Applicant: Industrial Technology Research Institute, Hsinchu (TW)

(72) Inventors: Hsuan-Fu Wang, Taoyuan City (TW); Fu-Ching Tung, Hsinchu City (TW); Ching-Chiun Wang, Miaoli County (TW)

(73) Assignee: Industrial Technology Research Institute, Hsinchu (TW)

(21) Appl. No.: 18/409,805

(22) Filed: Jan. 11, 2024

Related U.S. Application Data
(62) Division of application No. 17/546,053, filed on Dec. 9, 2021, now Pat. No. 11,961,716.

(51) Int. Cl. H01J 37/32; C23C 16/455

(52) U.S. Cl. CPC H01J 37/3244; C23C 16/45536; C23C 16/45548; C23C 16/45565; H01J 37/32899; H01J 37/32082; H01J 2237/332

(57) ABSTRACT

An atomic layer deposition apparatus including a chamber, a platform, a shower head, a bias power supply, a first injection device, and a second injection device is provided. The platform and the shower head are disposed in the chamber, and the platform is configured to carry a substrate having a high aspect ratio structure. The bias power supply is coupled to the platform. The first injection device and the second injection device are connected to the chamber; the first injection device injects a first precursor or a first inert gas into the chamber along a first direction through the shower head, and the second injection device injects a second precursor or a second inert gas into the chamber along a second direction perpendicular to the first direction. When the first precursor or the second precursor is injected into the chamber, the bias power supply is turned on. When the first inert gas or the second inert gas is injected into the chamber, the bias power supply is turned off.

### CROSS-REFERENCE TO RELATED APPLICATION

This application is a divisional application of and claims the priority benefit of U.S. application Ser. No. 17/546,053, filed on Dec. 9, 2021. The entirety of the above-mentioned patent application is hereby incorporated by reference herein and made a part of this specification.

### TECHNICAL FIELD

The disclosure relates to a deposition apparatus and more particularly relates to an atomic layer deposition (ALD) apparatus.

### DESCRIPTION OF RELATED ART

Atomic layer deposition (ALD) and plasma enhanced atomic layer deposition (PEALD) are widely used in semiconductor manufacturing processes to form a conformal thin film with a uniform thickness on the entire surface of a substrate. The ALD is similar to normal chemical vapor deposition (CVD).

A substrate having a high aspect ratio structure is taken as an example. The ALD technology is to inject precursors along a horizontal direction. Although a thin film with the uniform thickness may be formed in the high aspect ratio structure, a growth rate in a vertical direction is insufficient, and thus a coating efficiency may not be improved. In contrast, the PEALD technology is to inject the precursors in the vertical direction. Although the growth rate in the vertical direction may be increased, the thickness of the film formed in the high aspect ratio structure is not uniform, and thus coating uniformity may not be improved.

### SUMMARY

The disclosure provides an atomic layer deposition apparatus.

One of the embodiments of the disclosure provides an atomic layer deposition apparatus adapted to perform atomic layer deposition (ALD) on a high aspect ratio structure. The deposition apparatus includes a chamber, a platform, a shower head, a bias power supply, a first injection device, and a second injection device. The platform and the shower head are disposed in the chamber, and the platform is configured to carry a substrate having the high aspect ratio structure. The bias power supply is coupled to the platform. The first injection device and the second injection device are connected to the chamber, where the first injection device is configured to inject a first precursor or a first inert gas into the chamber along a first direction through the shower head, and the second injection device is configured to inject a second precursor or a second inert gas into the chamber along a second direction perpendicular to the first direction. The first injection device and the second injection device sequentially inject the first precursor through the shower head and the second precursor into the chamber. When the first precursor or the second precursor is injected into the chamber, the bias power supply is turned on. After the first precursor or the second precursor is injected into the chamber, the first injection device injects the first inert gas into the chamber, or the second injection device injects the second inert gas into the chamber, and the bias power supply is turned off.

Several exemplary embodiments accompanied with figures are described in detail below to further describe the disclosure in details.

### BRIEF DESCRIPTION OF THE DRAWINGS

FIG. 1A to FIG. 1H are schematic views of an atomic layer deposition apparatus according to a first embodiment to an eighth embodiment of the disclosure.

FIG. 2A to FIG. 2E are schematic partial enlarged views of an atomic layer deposition process on a high aspect ratio structure according to an embodiment of the disclosure.

FIG. 3A is a schematic flowchart of an atomic layer deposition method according to the first embodiment of the disclosure.

FIG. 3B is a schematic time sequence diagram illustrating the deposition method depicted in FIG. 3A.

FIG. 4A is a schematic flowchart of an atomic layer deposition method according to the second embodiment of the disclosure.

FIG. 4B is a schematic time sequence diagram illustrating the deposition method depicted in FIG. 4A.

FIG. 5A is a schematic flowchart of an atomic layer deposition method according to the third embodiment of the disclosure.

FIG. 5B is a schematic time sequence diagram illustrating the deposition method depicted in FIG. 5A.

FIG. 6A is a schematic flowchart of an atomic layer deposition method according to the fourth embodiment of the disclosure.

FIG. 6B is a schematic time sequence diagram illustrating the deposition method depicted in FIG. 6A.

FIG. 7A is a schematic flowchart of an atomic layer deposition method according to the fifth embodiment of the disclosure.

FIG. 7B is a schematic time sequence diagram illustrating the deposition method depicted in FIG. 7A.

### DETAILED DESCRIPTION OF DISCLOSED EMBODIMENTS

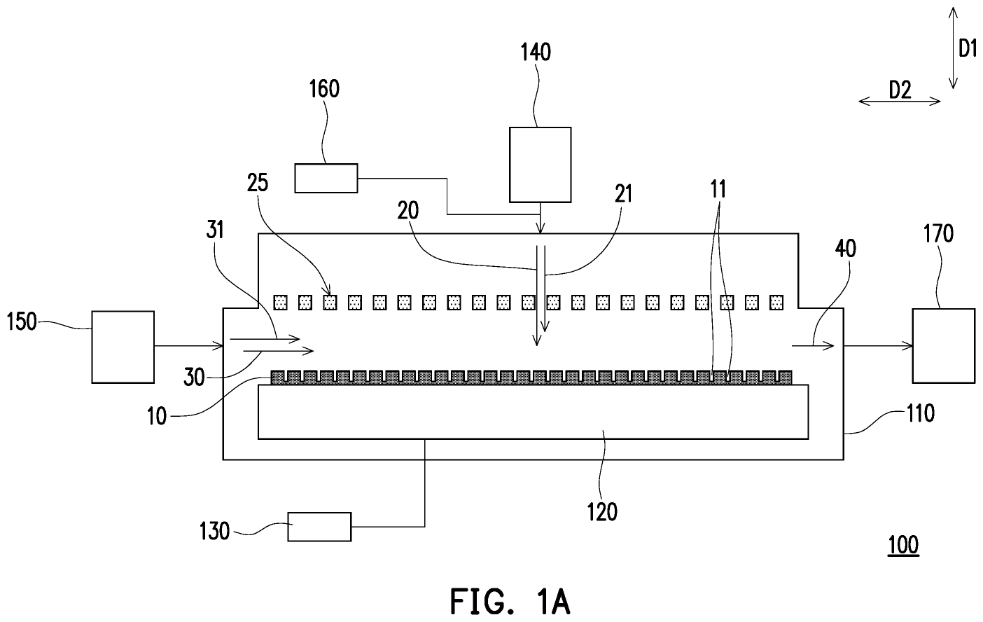

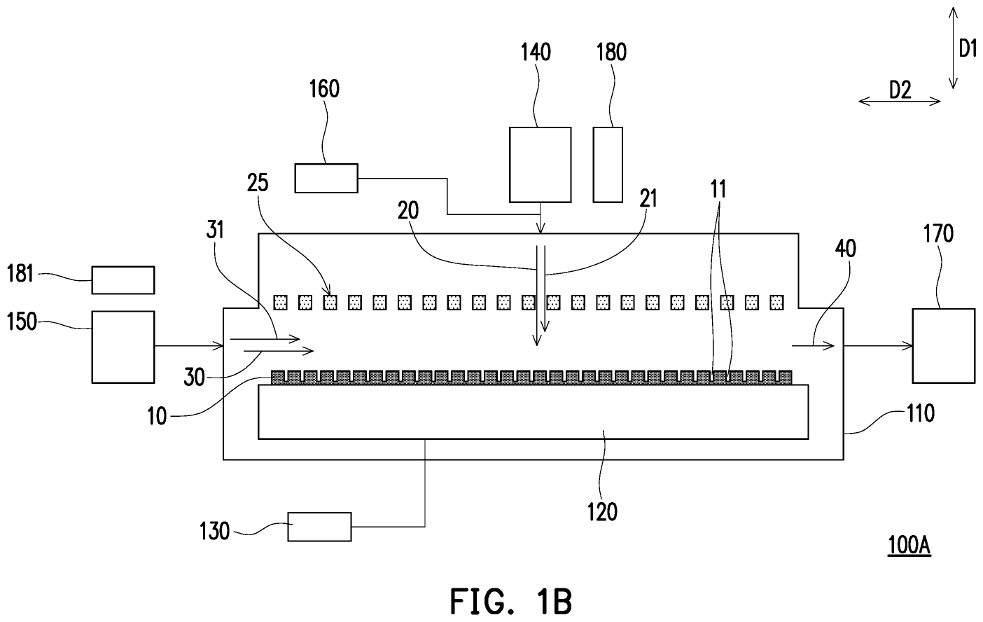

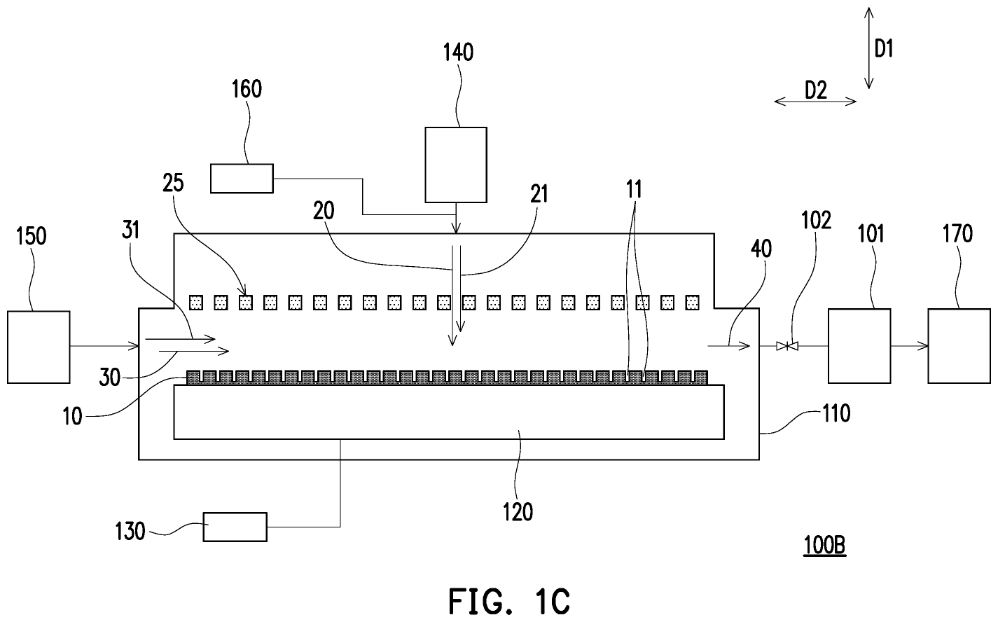

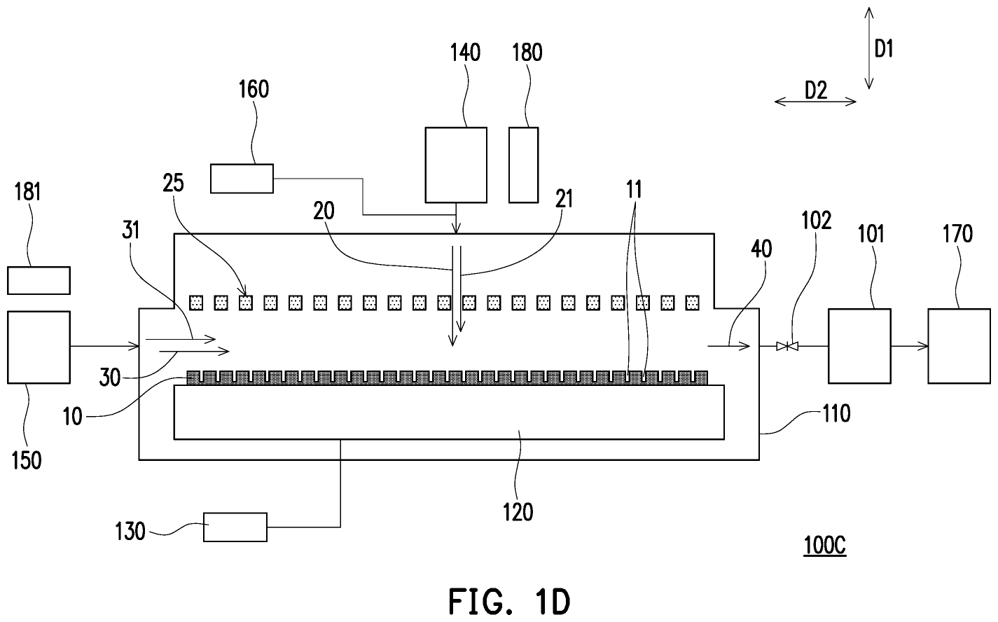

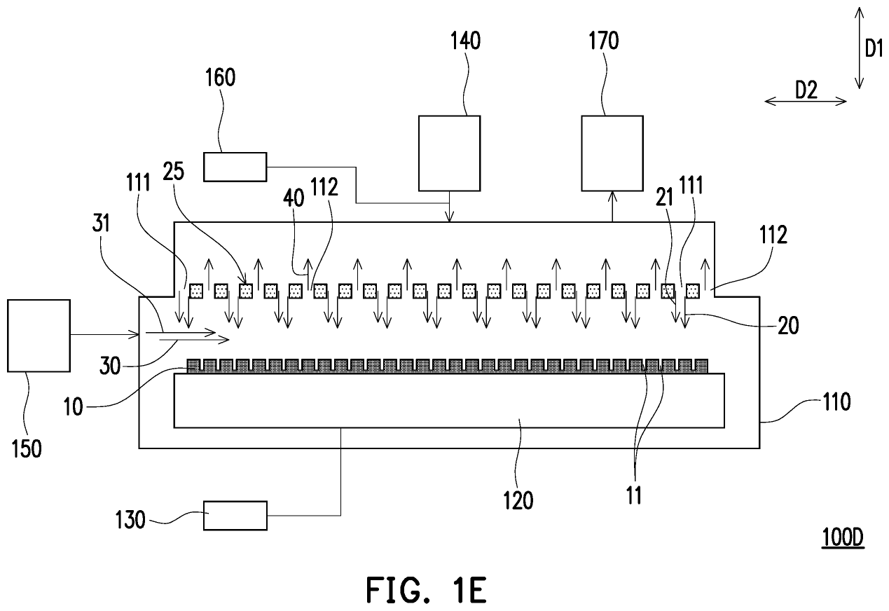

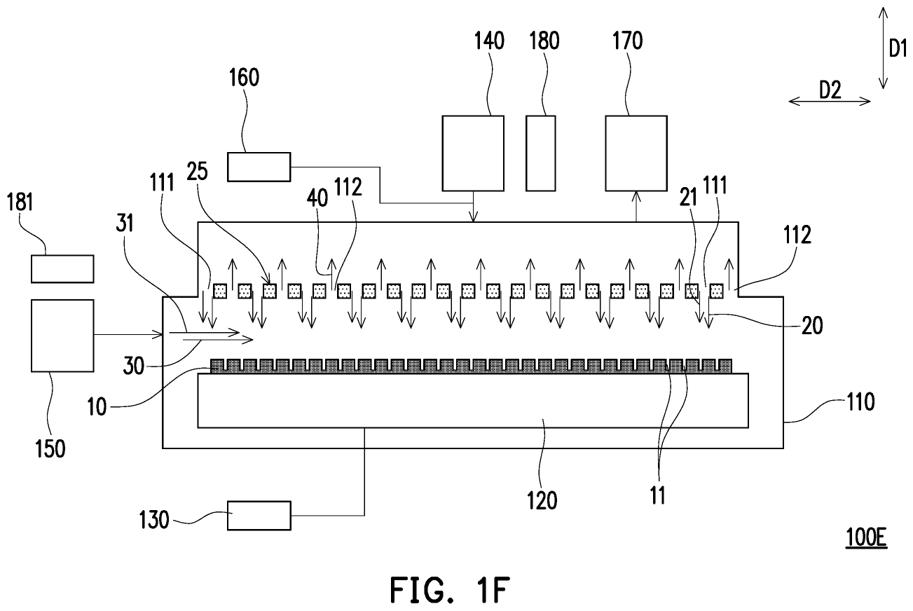

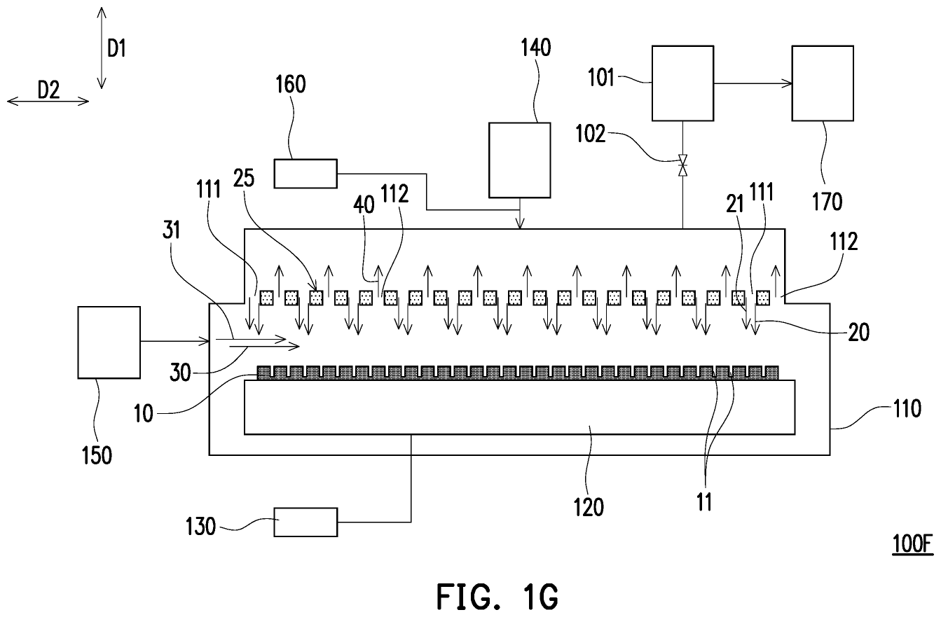

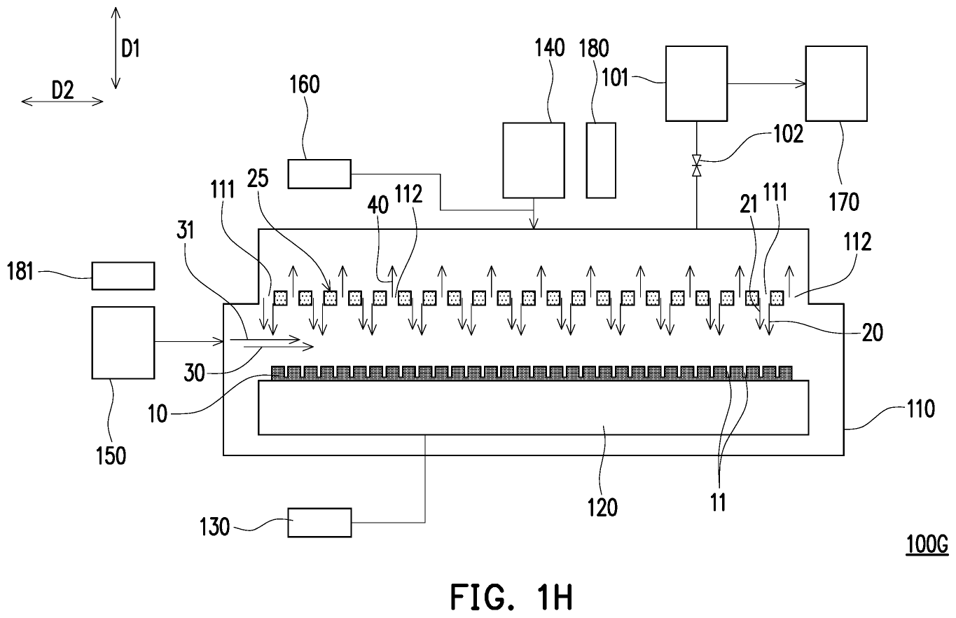

FIG. 1A to FIG. 1H are schematic views of an atomic layer deposition apparatus according to a first embodiment to an eighth embodiment of the disclosure. With reference to FIG. 1A, in the present embodiment, a deposition apparatus 100 may be an atomic layer deposition (ALD) apparatus and may be adapted to an ALD on a high aspect ratio structure. In detail, the deposition apparatus 100 includes a chamber 110, a platform 120, a shower head 25, a bias power supply 130, a first injection device 140, and a second injection device 150, where the platform 120 is disposed in the chamber 110, and a substrate 10 is disposed on the platform 120. On the other hand, the substrate 10 has a plurality of high aspect ratio structures 11, e.g., blind holes or grooves.

The shower head 25 is, corresponding to the first injection device 140, disposed in the chamber 110 and is located above the platform 120. The first injection device 140 and the second injection device 150 are connected to the chamber 110, where the first injection device 140 is configured to inject evenly a first precursor 20 or a first inert gas 21 into the chamber 110 through the shower head 25 along a first direction D1, and the second injection device 150 is configured to inject a second precursor 30 or a second inert gas 31 into the chamber 110 along a second direction D2 perpendicular to the first direction D1. To be specific, the first precursor 20 is evenly injected into the chamber 110 along the first direction D1 (e.g., a vertical direction) through the shower head 25 and flows toward the substrate 10 to form a down stream, which is conducive to acceleration of a growth rate of a thin film in the vertical direction. In contrast, the second precursor 30 is injected into the chamber 110 along the second direction D2 (e.g., a horizontal direction) and flows through the substrate 10 to form a cross flow, which is conducive to improvement of uniformity of the thin film formed in the high aspect ratio structures 11.

In the process where the first precursor 20 is evenly injected into the chamber 110 through the shower head 25, the first precursor 20 generates chemical absorption of one single atom layer on a surface of the substrate 10 and inner wall surfaces of the high aspect ratio structures 11, so that a functional group is generated on the surface of the substrate 10 and the inner wall surfaces of the high aspect ratio structures 11, which is a first half-reaction step. In the process where the second precursor 30 is injected into the chamber 110, the second precursor 30 reacts with the functional group of the first precursor 20 located on the surface of the substrate 10 and the inner wall surfaces of the high aspect ratio structures 11 to form one single atom layer, which is a second half-reaction step.

That is, in the first half-reaction step and the second half-reaction step, the first precursor 20 and the second precursor 30 are injected along two different directions, respectively, which is not only conducive to improvement of coating efficiency but also conducive to improvement of the uniformity of the thin film formed in the high aspect ratio structures 11.

As shown in FIG. 1A, the bias power supply 130 is electrically coupled to the platform 120. When the first precursor 20 or the second precursor 30 is injected into the chamber 110, the bias power supply 130 is turned on to apply a bias to the platform 120 and the substrate 10 thereon. Under the bias action, the first precursor 20 or the second precursor 30 is attracted to substrate 10 and moved into high aspect ratio structures 11, which is conducive to the improvement of the coating efficiency and uniformity.

After the first precursor 20 or the second precursor 30 is injected into the chamber 110, the first injection device 140 injects the first inert gas 21 into the chamber 110, or the second injection device 150 injects the second inert gas 31 into the chamber 110, and the bias power supply 130 is turned off, which is conducive to purge or clear the first precursor 20 or the second precursor 30 which blocks openings of the high aspect ratio structures 11 and allowing the first precursor 20 or the second precursor 30 to fall into the high aspect ratio structures 11 smoothly.

In particular, the first inert gas 21 is injected into the chamber 110 along the first direction D1 (e.g., the vertical direction) and flows toward the substrate 10 to accelerate the process where the first precursor 20 or the second precursor 30 falls into the high aspect ratio structures 11 and is spread over the inner wall surfaces of the high aspect ratio structures 11; at the same time, an unnecessary part of the first precursor or an unnecessary part of the second precursor is purged, which is a first purge step. On the other hand, the second inert gas 31 is injected into the chamber 110 along the second direction D2 (e.g., the horizontal direction) and flows through the substrate 10 to purge or clear the first precursor 20 or the second precursor 30 which blocks openings of the high aspect ratio structures 11, which is a second purge step.

In the deposition process provided in the first embodiment, the first half-reaction step, the second purge step, the second half-reaction step, and the first purge step are sequentially performed twice.

In the deposition process provided in the second embodiment, the first half-reaction step and the second purge step are sequentially performed twice, and the second half-reaction step and the first purge step are sequentially performed twice.

In the deposition process provided in the third embodiment, the first half-reaction step, the first purge step, the second half-reaction step, and the second purge step are sequentially performed twice.

In the deposition process provided in the fourth embodiment, the first half-reaction step, the first purge step, the second half-reaction step, and the first purge step are sequentially performed, and the first half-reaction step, the second purge step, the second half-reaction step, and the second purge step are sequentially performed.

In the deposition process provided in the fifth embodiment, the first half-reaction step and the first purge step are sequentially performed twice, and the second half-reaction step and the second purge step are sequentially performed twice.

With reference to FIG. 1A, which is a schematic diagram of the deposition apparatus according to the first embodiment, the deposition apparatus 100 in this embodiment further includes a radio frequency (RF) power supply 160 and an air pumping device 170, where the RF power supply 160 is electrically coupled to the first injection device 140 or electrically coupled to the shower head 25, and the RF power supply 160 is turned on when the first precursor 20 is injected; a dissociation reaction of the first precursor 20 is accelerated by generating plasma, and the bias power supply 130 may be turned on at the same time to apply a bias to the platform 120 and the substrate 10 thereon. Under the bias action, the first precursor 20 is attracted to the substrate 10 and moved into the high aspect ratio structures 11, which is conducive to the improvement of the coating efficiency and uniformity. In addition, the air pumping device 170 is connected to the chamber 110 and generates a pumping airflow 40 in the second direction D2. After the deposition process is completely performed, the air pumping device 170 is turned on to purge the unnecessary part of the first precursor 20 and the unnecessary part of the second precursor 30 from the chamber 110.

With reference to FIG. 1B, which is a schematic diagram of the deposition apparatus according to the second embodiment, a difference between a deposition apparatus 100A and the deposition apparatus 100 provided in the first embodiment depicted FIG. 1A lies in that the deposition apparatus 100A further includes a first heater 180 thermally coupled to the first injection device 140 and a second heater 181 thermally coupled to the second injection device 150. To be specific, when the first precursor 20 is injected into the chamber 110, the first heater 180 is turned on and heats the first precursor 20 to provide energy required the reaction of the first precursor 20. In addition, when the second precursor 30 is injected into the chamber 110, the second heater 181 is turned on and heats the second precursor 30 to provide energy required for the reaction of the second precursor 30.

With reference to FIG. 1C, which is a schematic diagram of the deposition apparatus according to the third embodiment, a difference between a deposition apparatus 100B and the deposition apparatus 100 provided in the first embodiment depicted FIG. 1A lies in that the deposition apparatus 100B further includes a low-pressure chamber 101 connected to the chamber 110, where the air pumping device 170 is connected to the low-pressure chamber 101, and the air pumping device 170 performs air pumping on the low-pressure chamber 101, so that the low-pressure chamber 101 remains in a state approaching the vacuum state, e.g. 10⁻⁴ torr.

To be specific, the air pumping device 170 is indirectly connected to the chamber 110 through the low-pressure chamber 101, and a pressure of the low-pressure chamber 101 is lower than a pressure of the chamber 110. In other words, there is a pressure difference between the chamber 110 and the low-pressure chamber 101. In particular, the deposition apparatus 100B further includes a valve 102 disposed between the chamber 110 and the low-pressure chamber 101. During the deposition process, the valve 102 is turned off. After the deposition process is completely performed, the valve 102 is turned on to communicate the chamber 110 and the low-pressure chamber 101 and generate a pumping airflow 40 in the second direction D2, so as to quickly purge the unnecessary part of the first precursor 20 and the unnecessary part of the second precursor 30 from the chamber 110.

With reference to FIG. 1D, which is a schematic diagram of the deposition apparatus according to the fourth embodiment, a difference between a deposition apparatus 100C and the deposition apparatus 100B provided in the third embodiment depicted FIG. 1C lies in that the deposition apparatus 100C further includes the first heater 180 thermally coupled to the first injection device 140 and the second heater 181 thermally coupled to the second injection device 150. The deposition apparatus 100C has the low-pressure chamber 101 connected to the chamber 110, and when the first precursor 20 is injected into the chamber 110, the first heater 180 is turned on and heats the first precursor 20 to provide energy required for the reaction of the first precursor 20. In addition, when the second precursor 30 is injected into the chamber 110, the second heater 181 is turned on and heats the second precursor 30 to provide the energy required for the reaction of the second precursor 30.

With reference to FIG. 1E, which is a schematic diagram of the deposition apparatus according to the fifth embodiment, a difference between a deposition apparatus 100D and the deposition apparatus 100 provided in the first embodiment depicted FIG. 1A lies in the arrangement of a flow path of the first precursor 20 and the pumping airflow 40. In the present embodiment, a plurality of air feeding channels 111 and a plurality of air pumping channels 112 are alternately arranged within the chamber 110, and the air feeding channels 111 and the air pumping channels 112 are located above the platform 120. In the present embodiment, the air feeding channels 111 and the air pumping channels 112 are located between the first injection device 140 and the platform 120.

In detail, the first injection device 140 is connected to the air feeding channels 111, and the first precursor 20 flows toward the substrate 10 through the air feeding channels 111. On the other hand, the air pumping device 170 is connected to the air pumping channels 112 to generate the pumping airflow 40 in the first direction D1. After the deposition process is completely performed, the air pumping device 170 is turned on to purge the unnecessary part of the first precursor 20 and the unnecessary part of the second precursor 30 from the chamber 110.

With reference to FIG. 1F, which is a schematic diagram of the deposition apparatus according to a sixth embodiment, a difference between a deposition apparatus 100E and the deposition apparatus 100D provided in the fifth embodiment depicted FIG. 1E lies in that the deposition apparatus 100E further includes the first heater 180 thermally coupled to the first injection device 140 and the second heater 181 thermally coupled to the second injection device 150. To be specific, when the first precursor 20 is injected into the chamber 110, the first heater 180 is turned on and heats the first precursor 20 to provide energy required for the reaction of the first precursor 20. In addition, when the second precursor 30 is injected into the chamber 110, the second heater 181 is turned on and heats the second precursor 30 to provide the energy required for the reaction of the second precursor 30.

With reference FIG. 1G, which is a schematic diagram of the deposition apparatus according to a seventh embodiment, a difference between a deposition apparatus 100F and the deposition apparatus 100D provided in the fifth embodiment depicted FIG. 1E lies in that the deposition apparatus 100F further includes the low-pressure chamber 101 connected to the chamber 110, where the air pumping device 170 is connected to the low-pressure chamber 101, and the air pumping device 170 performs air pumping on the low-pressure chamber 101, so that the low-pressure chamber 101 stays in a state approaching the vacuum state, e.g., 10⁻⁴ torr.

To be specific, the air pumping device 170 is indirectly connected to the chamber 110 through the low-pressure chamber 101, and the pressure of the low-pressure chamber 101 is lower than the pressure of the chamber 110. That is, there is a pressure difference between the chamber 110 and the low-pressure chamber 101. In particular, the deposition apparatus 100F further includes the valve 102 disposed between the chamber 110 and the low-pressure chamber 101. During the deposition process, the valve 102 is turned off. After the deposition process is completely performed, the valve 102 is turned on to communicate the chamber 110 and the low-pressure chamber 101 and generate the pumping airflow 40 in the first direction D1 to quickly purge the unnecessary part of the first precursor 20 and the unnecessary part of the second precursor 30 from the chamber 110.

With reference to FIG. 1H, which is a schematic diagram of the deposition apparatus according to an eighth embodiment, a difference between a deposition apparatus 100G and the deposition apparatus 100F provided in the seventh embodiment depicted FIG. 1G lies in that the deposition apparatus 100G further includes the first heater 180 thermally coupled to the first injection device 140 and the second heater 181 thermally coupled to the second injection device 150. The deposition apparatus 100G includes the low-pressure chamber 101 connected to the chamber 110, and when the first precursor 20 is injected into the chamber 110, the first heater 180 is turned on and heats the first precursor 20 to provide energy required for the reaction of the first precursor 20. In addition, when the second precursor 30 is injected into the chamber 110, the second heater 181 is turned on and heats the second precursor 30 to provide the energy required for the reaction of the second precursor 30.

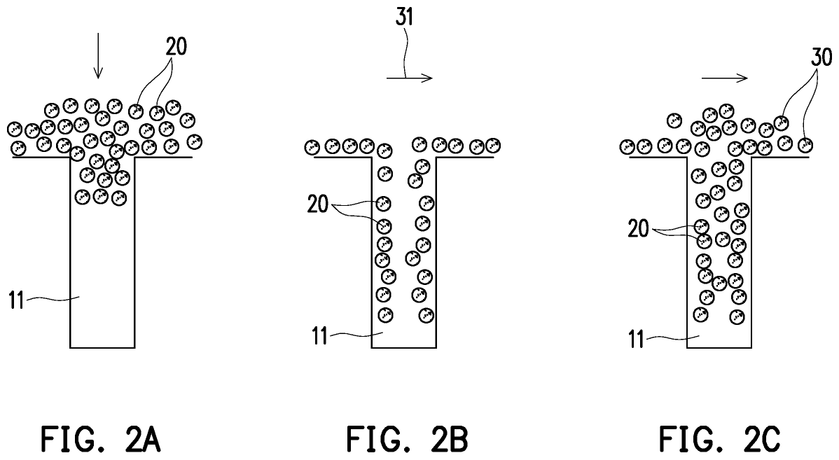

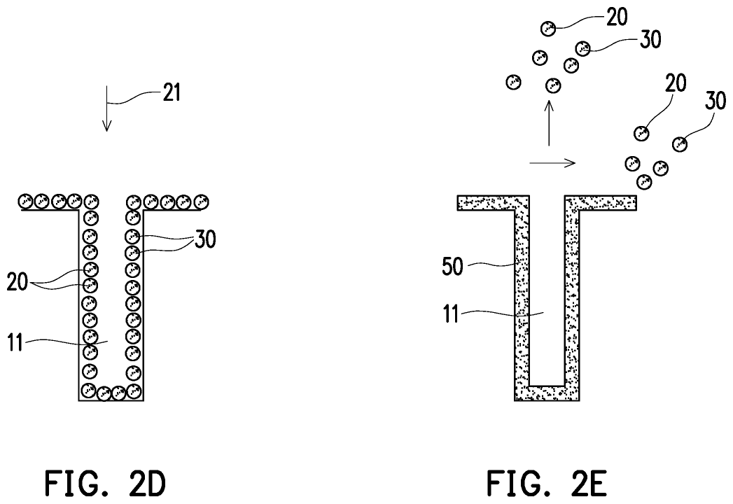

FIG. 2A to FIG. 2E are schematic partial enlarged views of an atomic layer deposition process on a high aspect ratio structure according to an embodiment of the disclosure. With reference to FIG. 1A and FIG. 2A, first, the first precursor 20 is evenly injected into the chamber 110 along the first direction D1 through the shower head 25 and flows toward the substrate 10. Next, as shown in FIG. 2B, the second inert gas 31 is injected into the chamber 110 along the second direction D2 to purge or clear the first precursor 20 blocked in the openings of the high aspect ratio structures 11, so that the first precursor 20 may fall into the high aspect ratio structures 11 smoothly, as shown in FIG. 2A and FIG. 2B. Next, with reference to FIG. 1A and FIG. 2C, the second precursor 30 is injected into the chamber 110 along the second direction D2 and flows through the substrate 10. Then, as shown in FIG. 2D, the first inert gas 21 is evenly injected into the chamber 110 along the first direction D1 through the shower head 25 and flows toward the substrate 10 to accelerate the speed at which the second precursor 30 falls into the high aspect ratio structures 11 and is spread over the inner wall surfaces of the high aspect ratio structures 11, as shown in FIG. 2C and FIG. 2D. Finally, a thin film 50 with a conformal uniform thickness is formed in the high aspect ratio structures 11, and the unnecessary part of the first precursor 20 and the unnecessary part of the second precursor 30 and by-products are purged, as shown in FIG. 2E.

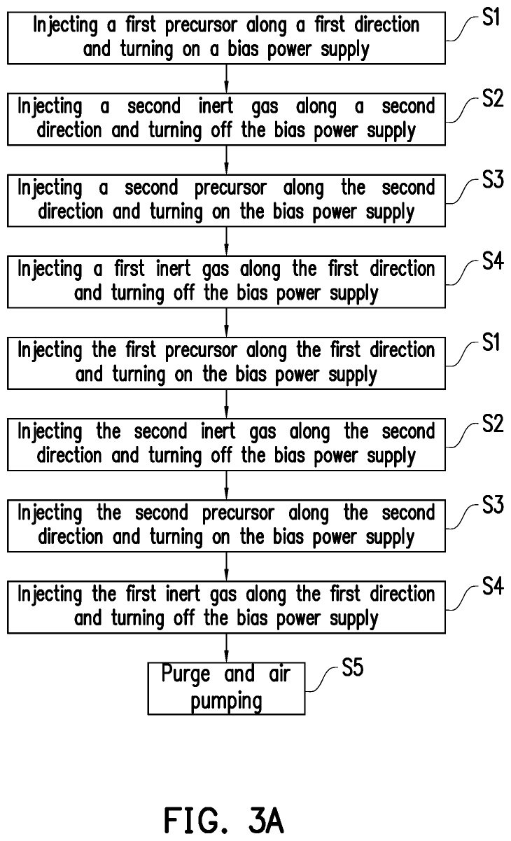

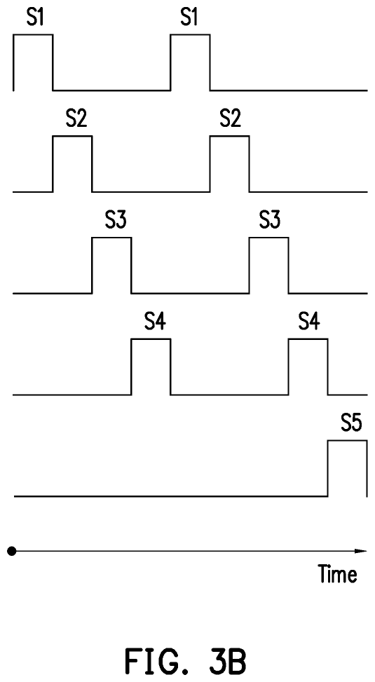

FIG. 3A is a schematic flowchart of an atomic layer deposition method according to the first embodiment of the disclosure. FIG. 3B is a schematic time sequence diagram illustrating the deposition method depicted in FIG. 3A. With reference to FIG. 3A and FIG. 3B, the deposition method may be performed by any of the deposition apparatus 100 and the deposition apparatuses 100A to 100G.

Specifically, the deposition method provided in the first embodiment includes the first reaction step and the second reaction step, as shown in FIG. 3A and FIG. 3B, where:
in the first reaction step, the first half-reaction step S1 (injecting the first precursor 20 along the first direction D1 and turning on the bias power supply 130) and the second purge step S2 (injecting the second inert gas 31 along the second direction D2 and turning off the bias power supply 130) are sequentially performed;
in the second reaction step, the second half-reaction S3 (injecting the second precursor 30 along the second direction D2 and turning on the bias power supply 130) and the first purge step S4 (injecting the first inert gas 21 along the first direction D1 and turning off the bias power supply 130) are sequentially performed.

As shown in FIG. 3A and FIG. 3B, the deposition method provided in the first embodiment of the disclosure includes alternately performing the first reaction step and the second reaction step twice. That is, the first half-reaction step S1, the second purge step S2, the second half-reaction step S3, and the first purge step S4 are sequentially performed, and the first half-reaction step S1, the second purge step S2, the second half-reaction step S3, and the first purge step S4 are sequentially performed again. Finally, purge and air pumping steps are performed (i.e., a cleaning step S5). In the cleaning step S5, an inert gas (e.g., the first inert gas 21 or the second inert gas 31) is injected to purge the unnecessary part of the first precursor 20, the unnecessary part of the second precursor 30, or other by-products, and the air pumping step is performed on the chamber 110 to pump out the unnecessary part of the first precursor 20, the unnecessary part of the second precursor 30, or other by-products from the chamber 110. Here, the cleaning step S5 may be omitted and should not be construed as a limitation in the disclosure.

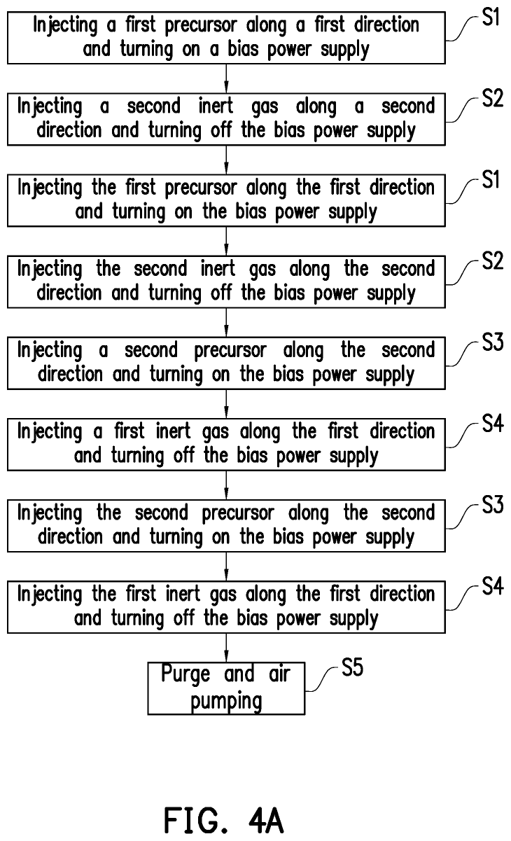

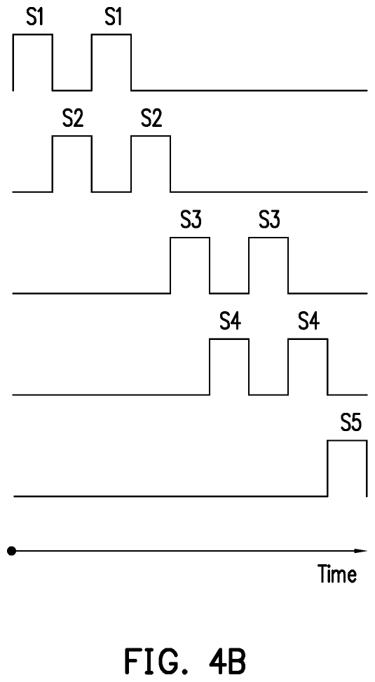

FIG. 4A is a schematic flowchart of an atomic layer deposition method according to the second embodiment of the disclosure. FIG. 4B is a schematic time sequence diagram illustrating the deposition method depicted in FIG. 4A. With reference to FIG. 4A and FIG. 4B, the deposition method may be performed by any of the deposition apparatus 100 and the deposition apparatuses 100A to 100G.

Specifically, the deposition method provided in the second embodiment includes the first reaction step and the second reaction step, as shown in FIG. 4A and FIG. 4B, where:
in the first reaction step, the first half-reaction step S1 (injecting the first precursor 20 along the first direction D1 and turning on the bias power supply 130) and the second purge step S2 (injecting the second inert gas 31 along the second direction D2 and turning off the bias power supply 130) are sequentially performed;
in the second reaction step, the second half-reaction S3 (injecting the second precursor 30 along the second direction D2 and turning on the bias power supply 130) and the first purge step S4 (injecting the first inert gas 21 along the first direction D1 and turning off the bias power supply 130) are sequentially performed.

As shown in FIG. 4A and FIG. 4B, the deposition method provided in the second embodiment of the disclosure includes performing the first reaction step twice and then performing the second reaction step twice. That is, the first half-reaction step S1, the second purge step S2, the first half-reaction step S1, and the second purge step S2 are sequentially performed, and the second half-reaction step S3, the first purge step S4, the second half-reaction step S3, and the first purge step S4 are sequentially performed. Finally, the purge and air pumping steps are performed (i.e., a cleaning step S5). In the cleaning step S5, an inert gas (e.g., the first inert gas 21 or the second inert gas 31) is injected to purge the unnecessary part of the first precursor 20, the unnecessary part of the second precursor 30, or other by-products, and the air pumping step is performed on the chamber 110 to pump out the unnecessary part of the first precursor 20, the unnecessary part of the second precursor 30, and/or other by-products from the chamber 110. Here, the cleaning step S5 may be omitted and should not be construed as a limitation in the disclosure.

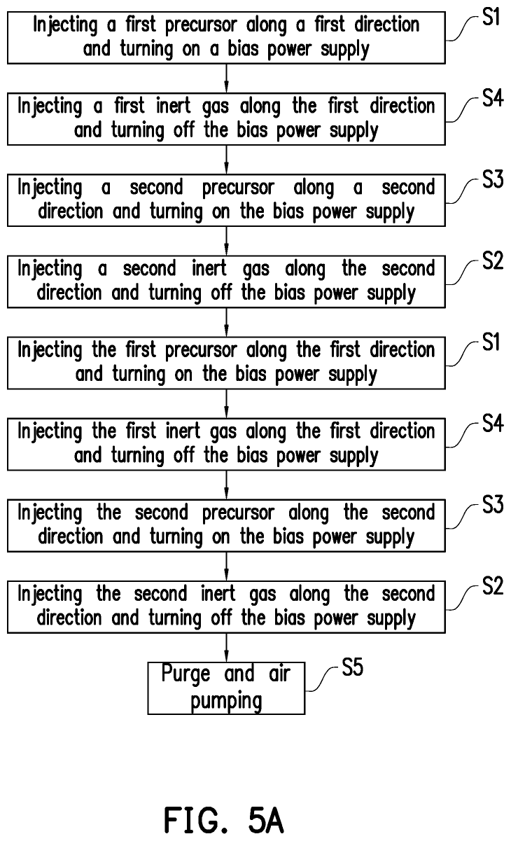

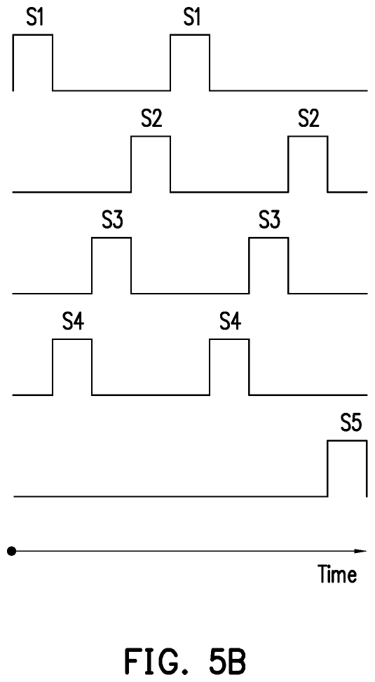

FIG. 5A is a schematic flowchart of an atomic layer deposition method according to the third embodiment of the disclosure. FIG. 5B is a schematic time sequence diagram illustrating the deposition method depicted in FIG. 5A. With reference to FIG. 5A and FIG. 5B, the deposition method may be performed by any of the deposition apparatus 100 and the deposition apparatuses 100A to 100G.

Specifically, the deposition method provided in the third embodiment includes the first reaction step and the second reaction step, as shown in FIG. 5A and FIG. 5B, where:
in the first reaction step, the first half-reaction step S1 (injecting the first precursor 20 along the first direction D1 and turning on the bias power supply 130) and the first purge step S4 (injecting the first inert gas 21 along the first direction D1 and turning off the bias power supply 130) are sequentially performed;
in the second reaction step, the second half-reaction S3 (injecting the second precursor 30 along the second direction D2 and turning on the bias power supply 130) and the second purge step S2 (injecting the second inert gas 31 along the second direction D2 and turning off the bias power supply 130) are sequentially performed.

As shown in FIG. 5A and FIG. 5B, the deposition method provided in the third embodiment of the disclosure includes alternately performing the first reaction step and the second reaction step twice. That is, the first half-reaction step S1, the first purge step S4, the second half-reaction step S3, and the second purge step S2 are sequentially performed, and the first half-reaction step S1, the first purge step S4, the second half-reaction step S3, and the second purge step S2 are sequentially performed again. Finally, the purge and air pumping steps are performed (i.e., a cleaning step S5). In the cleaning step S5, an inert gas (e.g., the first inert gas 21 or the second inert gas 31) is injected to purge the unnecessary part of the first precursor 20, the unnecessary part of the second precursor 30, or other by-products, and the air pumping step is performed on the chamber 110 to pump out the unnecessary part of the first precursor 20, the unnecessary part of the second precursor 30, and/or other by-products from the chamber 110. Here, the cleaning step S5 may be omitted and should not be construed as a limitation in the disclosure.

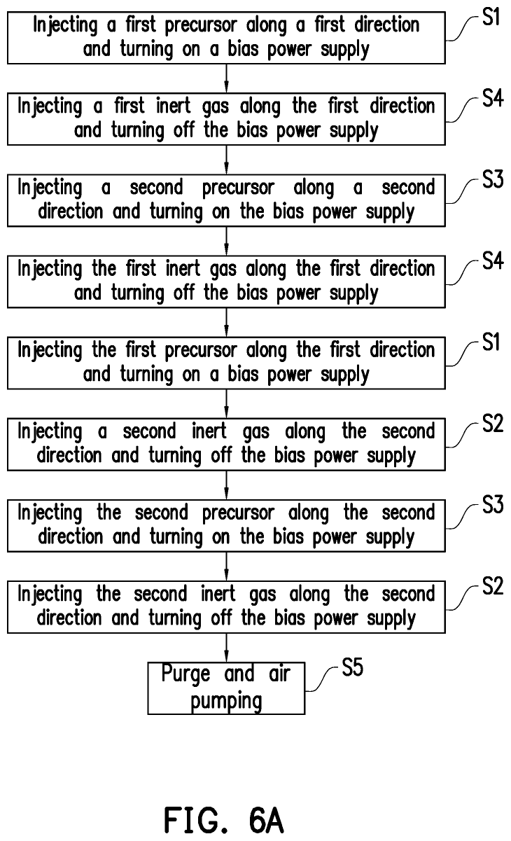

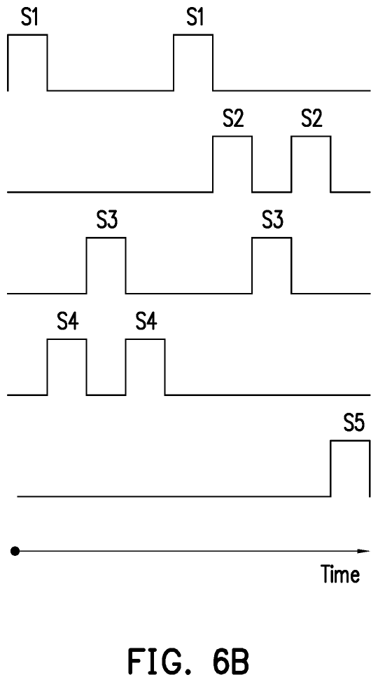

FIG. 6A is a schematic flowchart of an atomic layer deposition method according to the fourth embodiment of the disclosure. FIG. 6B is a schematic time sequence diagram illustrating the deposition method depicted in FIG. 6A. The deposition method may be performed by any of the deposition apparatus 100 and the deposition apparatuses 100A to 100G.

Specifically, the deposition method provided in the fourth embodiment includes the first reaction step to the fourth reaction step, as shown in FIG. 6A and FIG. 6B, where:
in the first reaction step, the first half-reaction step S1 (injecting the first precursor 20 along the first direction D1 and turning on the bias power supply 130) and the first purge step S4 (injecting the first inert gas 21 along the first direction D1 and turning off the bias power supply 130) are sequentially performed;
in the second reaction step, the second half-reaction S3 (injecting the second precursor 30 along the second direction D2 and turning on the bias power supply 130) and the first purge step S4 are sequentially performed;
in the third reaction step, the first half-reaction step S1 and the second purge step S2 (injecting the second inert gas 31 along the second direction D2 and turning off the bias power supply 130) are sequentially performed;
in the fourth reaction step, the second half-reaction S3 and the second purge step S2 are sequentially performed.

The deposition method provided in the fourth embodiment of the disclosure includes sequentially performing the first reaction step to the fourth reaction step. As shown in FIG. 6B, the first half-reaction step S1 and the first purge step S4 are sequentially performed, the second half-reaction S3 and the first purge step S4 are performed, the first half-reaction step S1 and the second purge step S2 are performed, and then the second half-reaction S3 and the second purge step S2 are performed. Finally, the purge and air pumping steps are performed (i.e., a cleaning step S5). In the cleaning step S5, an inert gas (e.g., the first inert gas 21 or the second inert gas 31) is injected to purge the unnecessary part of the first precursor 20, the unnecessary part of the second precursor 30, or other by-products, and the air pumping step is performed on the chamber 110 to pump out the unnecessary part of the first precursor 20, the unnecessary part of the second precursor 30, and/or other by-products from the chamber 110. Here, the cleaning step S5 may be omitted and should not be construed as a limitation in the disclosure.

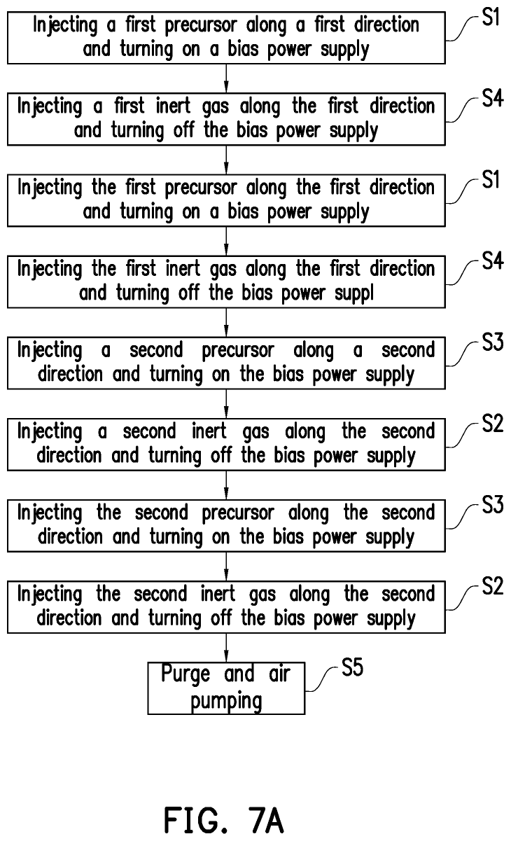

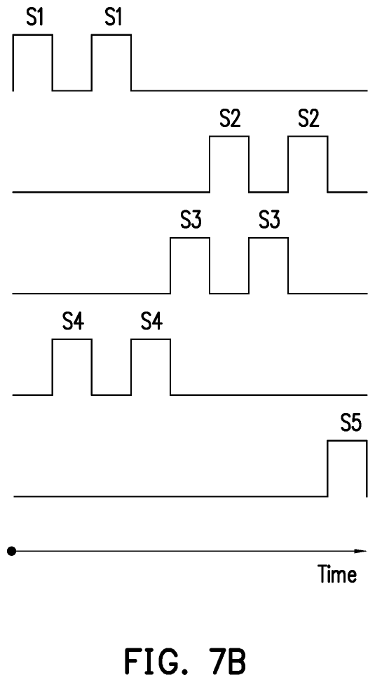

FIG. 7A is a schematic flowchart of an atomic layer deposition method according to the fifth embodiment of the disclosure. FIG. 7B is a schematic time sequence diagram illustrating the deposition method depicted in FIG. 7A.

Specifically, the deposition method provided in the fifth embodiment includes the first reaction step and the second reaction step, as shown in FIG. 7A and FIG. 7B, where:
in the first reaction step, the first half-reaction step S1 (injecting the first precursor 20 along the first direction D1 and turning on the bias power supply 130) and the first purge step S4 (injecting the first inert gas 21 along the first direction D1 and turning off the bias power supply 130) are sequentially performed;
in the second reaction step, the second half-reaction S3 (injecting the second precursor 30 along the second direction D2 and turning on the bias power supply 130) and the second purge step S2 (injecting the second inert gas 31 along the second direction D2 and turning off the bias power supply 130) are sequentially performed.

The deposition method provided in the fifth embodiment of the disclosure includes performing the first reaction step twice and then performing the second reaction step twice. As shown in FIG. 7B, the first half-reaction step S1, the first purge step S4, the first half-reaction step S1, and the first purge step S4 are sequentially performed, and then the second half-reaction step S3, the second purge step S2, the second half-reaction step S3, and the second purge step S2 are sequentially performed. Finally, the purge and air pumping steps are performed (i.e., a cleaning step S5). In the cleaning step S5, an inert gas (e.g., the first inert gas 21 or the second inert gas 31) is injected to purge the unnecessary part of the first precursor 20, the unnecessary part of the second precursor 30, and/or other by-products, and the air pumping step is performed on the chamber 110 to pump out the unnecessary part of the first precursor 20, the unnecessary part of the second precursor 30, and/or other by-products from the chamber 110. Here, the cleaning step S5 may be omitted and should not be construed as a limitation in the disclosure.

To sum up, in the atomic layer deposition apparatus and the deposition method provided in the disclosure, the first precursor and the second precursor are injected into the chamber along two directions perpendicular to each other, where the first precursor forms the down stream flowing toward the substrate (e.g., the vertical direction), and then the second precursor forms the cross flow flowing through the substrate (e.g., the horizontal direction). The alternate action of the down stream and the cross flow is not only conducive to acceleration of the growth rate of the thin film in the vertical direction but also conducive to improvement of the uniformity of the thin film formed in the high aspect ratio structures. In another aspect, during the alternate action of the down stream and the cross flow, the bias power supply is turned on, and the bias is applied to the platform and the substrate thereon. Under the bias action, the first and second precursors are attracted to the substrate and moved into the high aspect ratio structures, which is conducive to the improvement of the coating efficiency and uniformity.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An atomic layer deposition apparatus comprising:
a chamber;
a platform, disposed in the chamber and configured to carry a substrate;
a shower head, disposed in the chamber;
a bias power supply, coupled to the platform;
a first injection device, connected to the chamber and configured to inject a first precursor or a first inert gas into the chamber through the shower head along a first direction; and
a second injection device, connected to the chamber and configured to inject a second precursor or a second inert gas into the chamber along a second direction perpendicular to the first direction,
wherein the first injection device and the second injection device sequentially inject the first precursor and the second precursor into the chamber, when the first precursor or the second precursor is injected into the chamber, the bias power supply is turned on,
after the first precursor or the second precursor is injected into the chamber, the first injection device injects the first inert gas into the chamber, or the second injection device injects the second inert gas into the chamber, and the bias power supply is turned off.

2. The atomic layer deposition apparatus according to claim 1, further comprising:
a radio frequency power supply, coupled to the first injection device or the shower head.

3. The deposition apparatus according to claim 1, further comprising:
an air pumping device, connected to the chamber and generating a pumping airflow in the second direction.

4. The atomic layer deposition apparatus according to claim 1, further comprising:
a low-pressure chamber, connected to the chamber; and
an air pumping device, connected to the low-pressure chamber, wherein a pressure of the low-pressure chamber is lower than a pressure of the chamber, and a pumping airflow is generated in the second direction.

5. The atomic layer deposition apparatus according to claim 4, further comprising:
a valve, disposed between the low-pressure chamber and the chamber.

6. The atomic layer deposition apparatus according to claim 1, wherein a plurality of air feeding channels and a plurality of air pumping channels are alternately arranged within the chamber, and the air feeding channels and the air pumping channels are located above the platform, wherein the first injection device is connected to the air feeding channels, and the deposition apparatus further comprises an air pumping device connected to the air pumping channels, so as to generate a pumping airflow in the first direction.

7. The atomic layer deposition apparatus according to claim 1, wherein a plurality of air feeding channels and a plurality of air pumping channels are alternately arranged within the chamber, and the air feeding channels and the air pumping channels are located above the platform, wherein the first injection device is connected to the air feeding channels, and the deposition apparatus further comprises a low-pressure chamber connected to the air pumping channels and an air pumping device connected to the low-pressure chamber, wherein a pressure of the low-pressure chamber is lower than a pressure of the chamber, and a pumping airflow is generated in the first direction.

8. The atomic layer deposition apparatus according to claim 7, further comprising:
a valve, disposed between the low-pressure chamber and the chamber.

9. The atomic layer deposition apparatus according to claim 1, further comprising:
a first heater, thermally coupled to the first injection device to heat the first precursor; and
a second heater, thermally coupled to the second injection device to heat the second precursor.
